(19) United States
(12) Patent Application Publication
(10) Pub. No.: US 2007/0146190 A1
(43) Pub. Date: Jun. 28, 2007

(54) Display driving apparatus and method for controlling output gray voltage level

(75) Inventors: Hyoung-rae Kim, Hwaseong-si (KR); Jong-seon Kim, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/584,858

(22) Filed: Oct. 23, 2006

(30) Foreign Application Priority Data
Oct. 21, 2005 (KR) 10-2005-0099616

(51) Int. Cl. H03M 1/12

(52) U.S. Cl. 341/155

(57) ABSTRACT

A display driving apparatus and method adjusts output gray voltage levels applied to a display driving apparatus that converts input data into a corresponding output voltage and displays an image. The driving method includes generating a plurality of gray voltages N times more than the number of output gray voltages representing voltages between a maximum value and a minimum value of the output voltage required to represent the input data as the image; selecting a plurality of output gray voltages required to represent the image, from among the gray voltages N times more than the output gray levels, in response to a selection signal; and decoding the input data using the selected output gray voltages and generating the output voltage. The display driving apparatus and method reduce distortion of an output image without increasing the size of the entire circuit.

### CROSS-REFERENCE TO RELATED PATENT APPLICATION

This application claims the benefit of Korean Patent Application No. 10-2005-0099616, filed on Oct. 21, 2005, in the Korean Intellectual Property Office, the disclosure of which is incorporated herein in its entirety by reference.

### BACKGROUND OF THE INVENTION

1. Technical Field

The present disclosure relates to a display driving apparatus and a driving method thereof and, more particularly, to an apparatus and method for analyzing an image histogram and obtaining an image without loss of gray levels.

2. Discussion of the Related Art

In display apparatuses for mobile devices, when image data with various brightness levels is received or when a change occurs in the brightness of a back light, output gray levels must be adjusted in order to obtain optimal picture quality.

Conventional display apparatuses for mobile devices use 6 bit gray level resolution. In the conventional display apparatuses, a display screen will actually represent only 4 bits of display resolution resulting in the loss of about 2 bits due to changes of image data or of the brightness of a back light, when output gray levels are adjusted using 6 bit gray level resolution.

FIG. 1 is a block diagram of a conventional display driving apparatus 100.

Referring to FIG. 1, the conventional display driving apparatus 100 includes a latch 110, a gray voltage generator 120, a decoding unit 130, and a histogram analysis and image-processing unit 140. The latch 110 receives and stores input data ID. The gray voltage generator 120 generates gray voltages GV having a plurality of voltages levels.

FIG. 1 shows that the gray voltage generator 120 generates gray voltages GV having 64 values, that is, 64 voltage levels are generated. The decoding unit 130 includes a plurality of decoders D, wherein each decoder D decodes the input data ID received from the latch 110 using a gray voltage GV provided by the gray voltage generator 120 and outputs an output voltage OV corresponding to the input data ID.

The output voltage OV drives a display cell (not shown) so that an image is created on a screen. The histogram analysis and image-processing unit 140 analyzes. an image histogram of the input data ID, performs image-processing on the analyzed result, and provides the resultant input data ID to the latch 110.

FIGS. 2A through 2F illustrate various input/output characteristics.

An input/output characteristic represents a relationship between a gray level of input data ID and a gray level of the corresponding decoded output voltage OV. As illustrated in FIG. 2A, if an input/output characteristic is linear, a display apparatus will display only predetermined images regardless of a change of peripheral light or the characteristic of input data ID. In this case, an image can be invisible due to peripheral light or the brightness of a back light.

For this reason, a non-linear input/output characteristic capable of providing optimal display screens with respect to specific images is required.

FIGS. 2B and 2C illustrate input/output characteristics in which images are well represented when a back light is dark or when an image histogram is in a low gray level region.

That is, when objects are not clearly distinguished because a screen is dark, a display apparatus having the input/output characteristics as illustrated in FIGS. 2B and 2C compensates for image characteristics so that images can be well displayed on the screen. FIGS. 2E and 2F illustrate input/output characteristics which correct a bright screen and display an enhanced screen when a back light is bright or when an image histogram is in a high gray level region.

FIG. 2D illustrates an input/output characteristic that makes a dark region appear darker and a bright region appear brighter in order to enhance picture quality by analyzing an image histogram.

In order to represent various input/output characteristics as illustrated in FIGS. 2A through 2F, the histogram analysis and image-processing unit 140 illustrated in FIG. 1 receives input data ID, analyzes a histogram of the input data ID, corrects the input data ID according to the analysis result, and outputs the corrected input data to the latch. 110 so that a proper image can be represented.

FIGS. 3A through 3F illustrate distortion phenomena of the input/output characteristics illustrated in FIGS. 2A through 2F.

FIGS. 3A through 3F are views for explaining an image distortion. The image distortion occurs in the region where differences between gray levels of output voltages of an image to be output are small. Referring to FIGS. 3B through 3F, due to quantization noise caused by quantization of output gray levels, image distortion occurs in the regions surrounded by circles.

As illustrated in FIGS. 3B through 3F, in the regions surrounded by circles, there is a case where the same output gray level appears when input gray levels are different from each other, and a case where output gray levels sharply change when input gray levels increase at the same ratio.

These phenomena reduce the number of gray levels that can be represented.

When these phenomena occur, although 6 bits of input data ID are received, only about 4 bits are assigned to an output gray level that can be actually represented. Thus, a screen corresponding to the 4 bits is displayed.

Accordingly, when a sharp change in brightness occurs while various gray levels, such as a human's face, are being represented, the human's face will be very roughly represented.

As described above, the conventional display driving apparatus cannot obtain optimal screens due to distortion of gray levels. Therefore, a new display driving apparatus and method that are capable of optimally representing original images are required.

### SUMMARY OF THE INVENTION

Exemplary embodiments of the present invention provide a display driving apparatus that is capable of representing images without distortion of gray levels.

Exemplary embodiments of the present invention also provide a display driving method that is capable of representing images without distortion of gray levels.

According to an exemplary embodiment of the present invention, there is provided a method of driving a display driving apparatus, wherein the display driving apparatus converts input data into a corresponding output voltage and displays an image, the method comprising: generating a plurality of gray voltages N times more than a number of output gray voltages that represent voltages between a maximum value and a minimum value of the output voltage required to represent the input data as the image; selecting a plurality of output gray voltages required to represent the image, among the gray voltages N times more than the output gray voltages, in response to a selection signal; and decoding the input data using the selected output gray voltages and generating the output voltage.

According to an exemplary embodiment of the present invention, there is provided a display driving apparatus that converts input data into a corresponding output voltage and displays an image, comprising: a gray voltage generator generating a plurality of gray voltages N times more than a number of output gray voltages that represent voltage levels between a maximum value and a minimum value of the output voltage required to represent the input data as the image; a gray voltage selector selecting a plurality of output gray voltages required to represent the image, from among the gray voltages N times more than the output gray voltages, in response to a selection signal; and a decoding unit decoding the input data using the selected output gray voltages and generating the output voltage.

According to an exemplary embodiment of the present invention, there is provided a method of driving a display driving apparatus comprising: analyzing an image histogram of M (M is a natural number) bits of input data and outputting M+K bits of corrected input data; and latching the M+K bits of the corrected input data; and decoding the M+K bits of the corrected input data using a plurality of gray voltages and generating an output voltage, wherein the number of gray voltages corresponds to the M+K bits of the corrected input data.

According to an exemplary embodiment of the present invention, there is provided a display driving apparatus comprising: a histogram analysis and image-processing unit analyzing an image histogram of M (M is a natural number) bits of input data and outputting M+K bits of corrected input data; a latch storing and outputting the M+K bits of the corrected input data; a gray voltage generator outputting a gray level corresponding to the M+K bits of the corrected input data; and a decoding unit decoding the M+K bits of the corrected input data output from the latch using the gray voltages and generating an output voltage.

### BRIEF DESCRIPTION OF THE DRAWINGS

Exemplary embodiments of the present invention will be understood in more detail from the following descriptions taken in conjunction with the attached drawings in which:

FIG. 1 is a block diagram of a conventional display driving apparatus;

FIGS. 2A through 2F illustrate various input/output characteristics;

FIGS. 3A through 3F illustrate distortion phenomena of the input/output characteristics illustrated in FIGS. 2A through 2F;

FIG. 4 is a flowchart illustrating a driving method of a display driving apparatus, according to an exemplary embodiment of the present invention;

FIG. 5 is a block diagram of a display driving apparatus performing the driving method illustrated in FIG. 4, according to an exemplary embodiment of the present invention;

FIG. 6 is a flowchart illustrating a driving method of a display driving apparatus, according to an exemplary embodiment of the present invention; and

FIG. 7 is a block diagram of a display driving apparatus performing the driving method of FIG. 6, according to an exemplary embodiment of the present invention.

### DETAILED DESCRIPTION OF EXEMPLARY EMBODIMENTS

The present invention will now be described more fully with reference to the accompanying drawings, in which exemplary embodiments of the invention are shown. The invention may, however, be embodied in many different forms and should not be construed as being limited to the exemplary embodiments set forth herein; rather, these exemplary embodiments are provided so that this disclosure will be thorough and complete, and will fully convey the concept of the invention to those skilled in the art. Like reference numerals in the drawings denote like elements, and thus their descriptions will not be repeated.

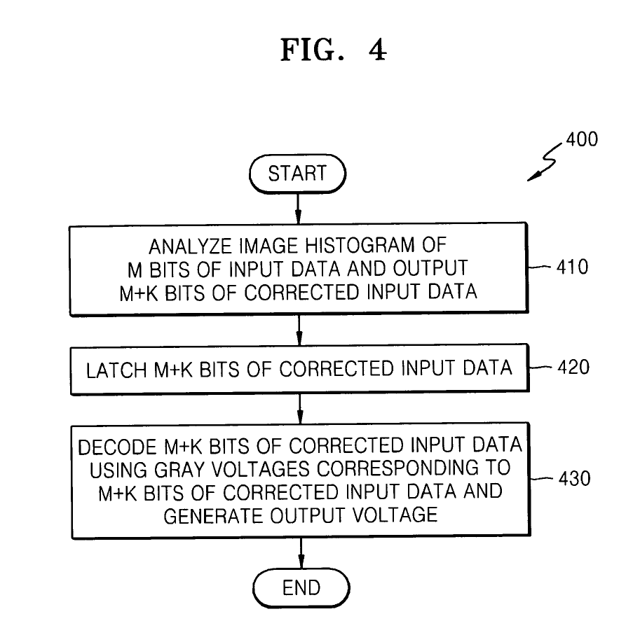

FIG. 4 is a flowchart illustrating a driving method 400 of a display driving apparatus, according to an exemplary embodiment of the present invention.

Referring to FIG. 4, the driving method 400 includes the steps of: analyzing an image histogram of M (M is a natural number) bits of input data and outputting M+K bits of corrected input data (operation 410); latching the M+K bits of the corrected input data (operation 420); and decoding the M+K bits of the corrected input data using a plurality of gray voltages and generating an output voltage (operation 430). The number of gray voltages corresponds to the number, for example, M+K bits, of bits of the corrected input data.

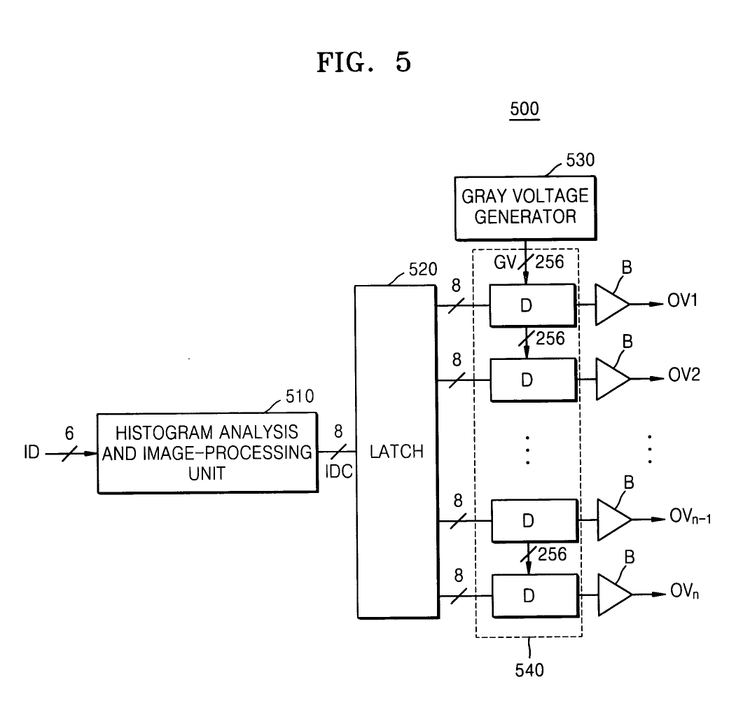

The driving method 400 illustrated in FIG. 4 corresponds to the operation of a display driving apparatus 500 illustrated in FIG. 5. Accordingly, the driving method 400 will be described together with the display driving apparatus 500 illustrated in FIG. 5 below.

FIG. 5 is a block diagram of the display driving apparatus 500 performing the driving method 400 illustrated in FIG. 4, according to an exemplary embodiment of the present invention.

Referring to FIG. 5, the display driving apparatus 500 includes a histogram analysis and image-processing unit 510, a latch 520, a gray voltage generator 530, and a decoding unit 540.

The histogram analysis and image-processing unit 510 analyzes an image histogram of M bits (M is a natural number) of input data ID and outputs M+K bits of corrected input data IDC, wherein K is a natural number.

K may be equal to the number of bits of input data ID lost due to image distortion. That is, the histogram analysis and image-processing unit 510 generates corrected input data IDC having the number of bits increased by the number of lost bits, corresponding to the number of bits of input data ID lost during display due to image distortion. In the exemplary embodiment of the present invention illustrated in FIG. 5, M may be 6 and K may be 2.

In more detail, the histogram analysis and image-processing unit 510 receives 6 bits of input data ID, analyzes an image histogram of the input data ID, and outputs 8 bits of corrected input data IDC.

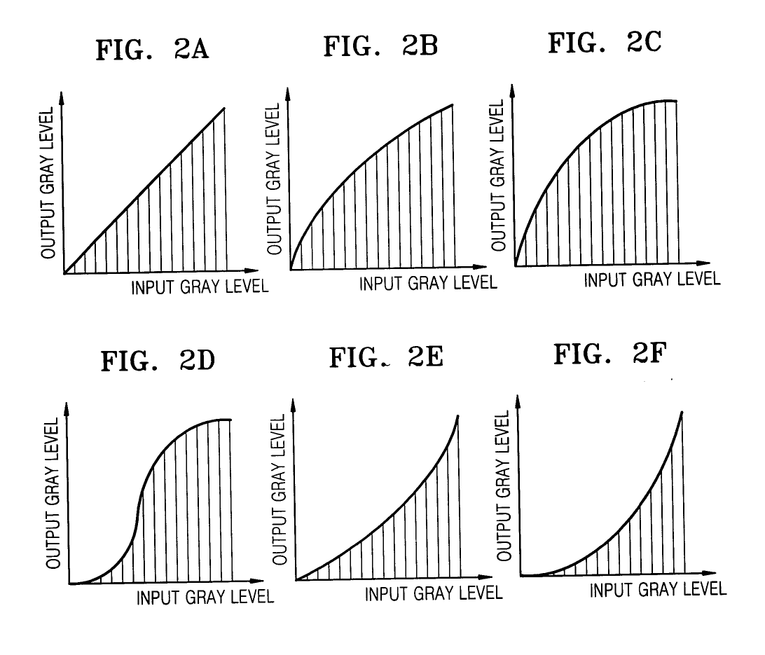

According to the analysis result of the image histogram of the input data ID, the corrected input data IDC corresponding to one of various input/output characteristic curves illustrated in FIGS. 2A through 2F is output.

In the current exemplary embodiment of the present invention, 8 bits of corrected input data IDC, in which 2 bits have been added to the input data ID, are output.

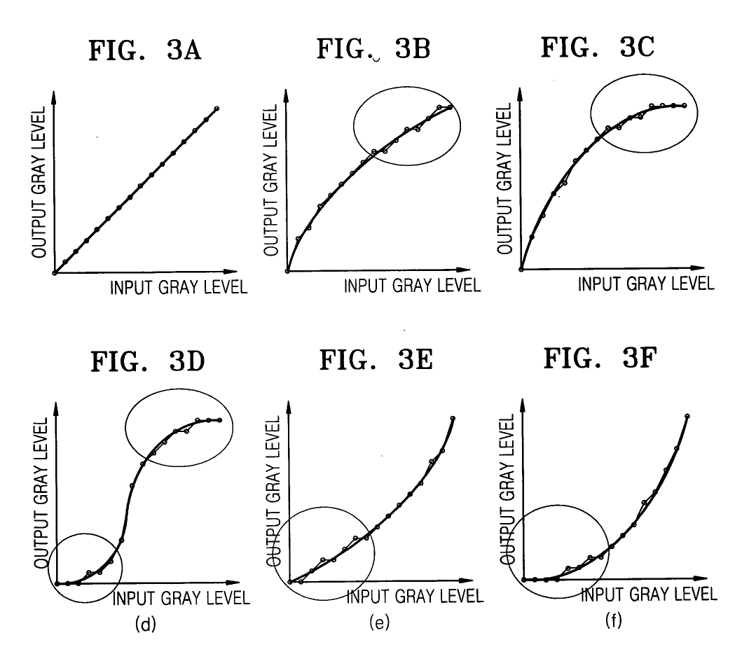

Since the 8 bits of corrected input data IDC are output, quantization noise as illustrated in FIGS. 3A through 3F is reduced and, thus, an image similar to an original image can be displayed. The latch 520 stores the corrected input data IDC and then outputs it.

The gray voltage generator 530 outputs a plurality of gray voltages GV corresponding to a number of different values that can be obtained by the number (for example, M+K) of bits of the corrected input data IDC. The decoding unit 540 decodes the M+K bits of the corrected input data IDC output from the latch 520 using the gray voltages GV, and generates output voltages OVₗ, through OVₙ.

The decoding unit 540 includes a plurality of decoders D. Each decoder D selects a gray voltage corresponding to the corrected input data IDC from among 256 gray voltages and outputs an output voltage OVₗ, through OVₙ. The output voltages OVₗ through OVₙ are provided to a display apparatus for use in displaying an image.

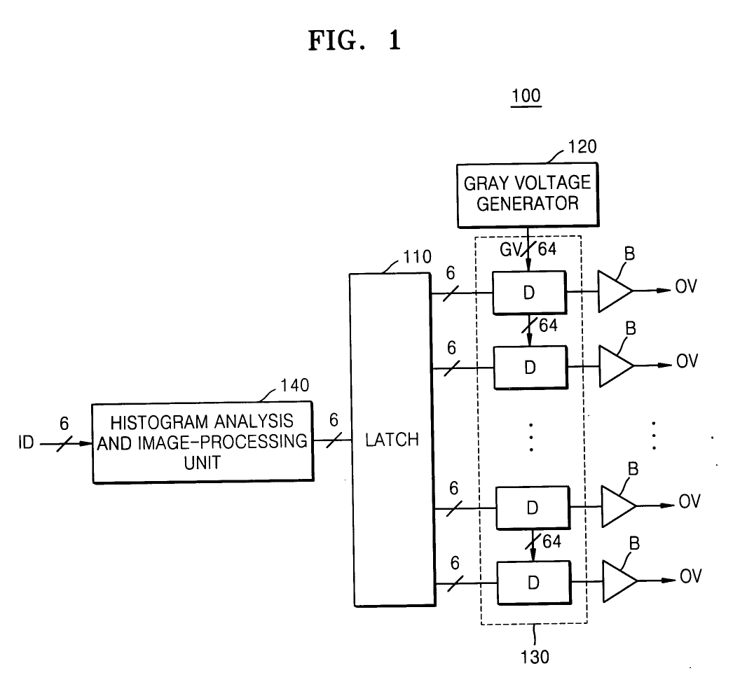

Since the display driving apparatus 500 illustrated in FIG. 5 additionally supplies data corresponding to the number of the lost bits to the decoding unit 540, corresponding to the number of bits of input data ID lost due to image distortion, and generates output voltages OVₗ through OVₙ using a plurality of gray voltages corresponding to the increased number of bits, differently from the conventional display driving apparatus 100 illustrated in FIG. 1. Accordingly, it is possible to represent images without distortion.

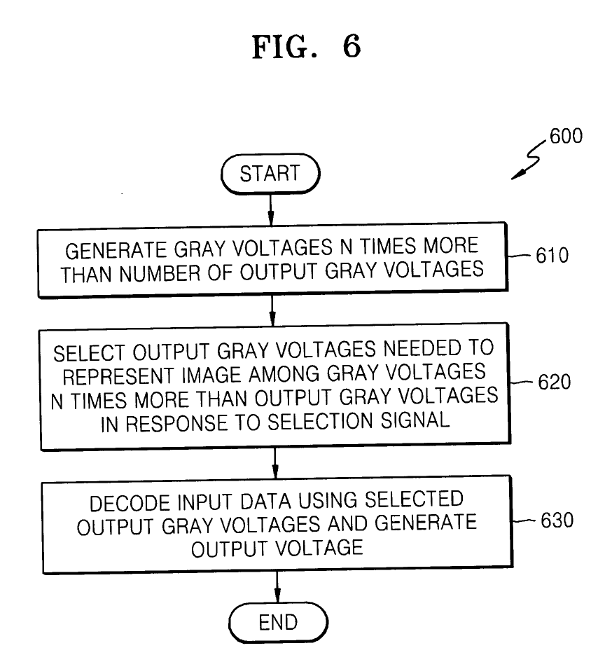

FIG. 6 is a flowchart illustrating a driving method 600 of a display driving apparatus, according to an exemplary embodiment of the present invention.

Referring to FIG. 6, the driving method 600 is applied to a display driving apparatus that converts input data into the corresponding output voltages and displays an image.

The driving method 600 includes generating gray voltages N times more than the number of output gray voltages that are voltage levels between a maximum value and a minimum value of an output voltage required to represent input data as an image (operation 610); selecting a plurality of output gray voltages needed to represent the image, among the gray voltages N times more than the number of output gray voltages, in response to a selection signal (operation 620); and decoding the input data using the selected output gray voltages and generating the output voltage (operation 630).

The driving method 600 may further include analyzing an image histogram of the input data and generating the selection signal.

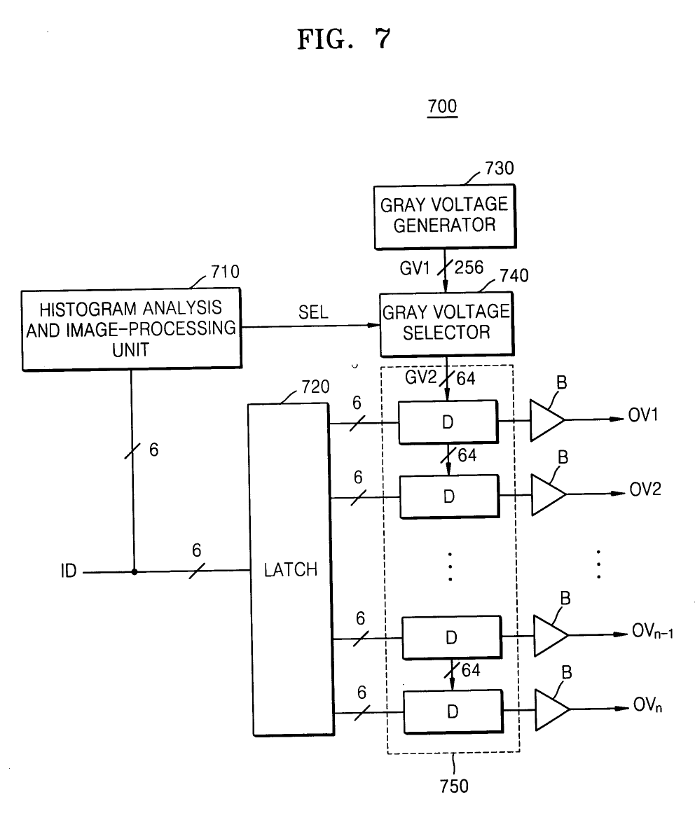

The driving method 600 illustrated in FIG. 6 corresponds to the operation of a display driving apparatus 700 illustrated in FIG. 7. Accordingly, the driving method 600 will be described together with the display driving apparatus 700 illustrated in FIG. 7 below.

FIG. 7 is a block diagram of a display driving apparatus 700 performing the driving method 600 of FIG. 6, according to an exemplary embodiment of the present invention.

Referring to FIG. 7, the display driving apparatus 700, which converts input data ID into the corresponding output voltage and displays an image, includes a histogram analysis and image-processing unit 710, a latch 720, a gray voltage generator 730, a gray voltage selector 740, and a decoding unit 750.

For the convenience of explanation, buffers B for buffering data output from the latch 720 and the decoding unit 750, are disclosed.

The latch 720 stores the input data ID and then outputs it to the decoding unit 750. More specifically, the latch 720 receives and stores 6 bits of input data ID and then outputs them to the decoding unit 750.

The histogram analysis and image-processing unit 710 analyzes an image histogram of the input data ID and generates a selection signal SEL. That is, the histogram analysis and image-processing unit 710 analyzes an image histogram of the input data ID, determines whether the corresponding image is bright or dark and whether the image histogram is in a low gray level region or in a high gray level region, and outputs a selection signal SEL.

The histogram analysis and image-processing unit 710 may generate a selection signal SEL using a predetermined color lookup table according to the analysis result of the image histogram of the input data ID.

If the image histogram of the input data ID is in the low gray level region, the histogram analysis and image-processing unit 710 generates a selection signal SEL for selecting output gray voltages GV2 of the region where a ratio of the output gray level with respect to the gray level of the input data ID is less than 1.

If the image histogram of the input data ID is in the high gray level region, the histogram analysis and image-processing unit 710 generates a selection signal SEL for selecting output gray voltages GV2 of the region where a ratio of the output gray level GV2 to the gray level of the input data is greater than 1.

The gray voltage generator 730 generates a number of gray voltages GV1 that are N times more than a number of output gray voltages GV2 that are voltage levels between a maximum value and a minimum value of the output voltage required to represent the input data ID as the image.

The gray voltage selector 740 selects output gray voltages GV2 needed to represent the image, among the gray voltages GV1 that are N times more than the output gray voltages GV2, in response to the selection signal SEL.

That is, 64 output gray voltages GV2 are selected from among 256 gray voltages GV1 according to the selection signal SEL output from the histogram analysis and image-processing unit 710.

As such, since 64 output gray voltages GV2 are selected after 256 gray voltages GV1 are generated, distortion of gray levels due to quantization noise is reduced.

FIG. 7 illustrates a case where the number of output gray voltages GV2 is 64 and the number of gray voltages GV1 is 256, which is 4 times more than the number of output gray voltages. The number of the output gray voltages GV2 and the number of the gray voltages GV1, however, are not limited to these.

The decoding unit 750 decodes the input data ID using the selected output gray voltages. GV2 and outputs voltages OVₗ through OVₙ. More specifically, the decoding unit 750 decodes 6 bits of input data ID received from the latch 720 using. the selected 64 bits of output gray voltages GV2 and generates output voltages OVₗ through OVₙ.

The decoding unit 750 includes a plurality of decoders D for decoding the corresponding input data ID and generating the output voltages OVₗ through OVₙ.

That is, the decoders D decode the input data ID received from the latch 720 using the 64 gray voltages GV2 and generate the output voltages OVₗ through OVₙ. The output voltages OVₗ through OVₙ are provided to a display apparatus for displaying an image.

The gray voltage generator 730 generates 256 gray voltages GV1, which is 4 times as many as the 64 gray voltages GV2 of the input data ID. To generate 256 gray voltages GV1, a resistor chain included in the gray voltage generator 730 is divided into 256 parts instead of being divided into 64 parts. Therefore, the size of the entire circuit is not increased.

Then, the gray voltage selector 740 selects 64 gray voltages GV2 from among the available 256 gray voltages GV1, and the decoding unit 750 uses the 64 gray voltages GV2. Accordingly, the decoding unit 750 can have a circuit area smaller than that of the decoding unit 540 illustrated in FIG. 5.

The display driving apparatus 700 illustrated in FIG. 7 can reduce distortion of an image of input data ID without increasing the size of the entire circuit.

As described above, in a display driving apparatus and method according to exemplary embodiments of the present invention, by analyzing an image histogram of input data and selectively decoding optimal gray voltages among a plurality of gray voltage levels more than what is required, it is possible to represent a screen having no image distortion without increasing the size of the entire circuit.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of driving a display driving apparatus, wherein the display driving apparatus converts input data into a corresponding output voltage and displays an image, the method comprising:
generating a plurality of gray voltages N times more than a number of output gray voltages that represent voltages between a maximum value and a minimum value of the output voltage required to represent the input data as the image;
selecting a plurality of output gray voltages required to represent the image, from among the gray voltages N times more than the output gray voltages, in response to a selection signal; and
decoding the input data using the selected plurality of output gray voltages and generating the corresponding output voltage.

2. The method of claim 1, wherein after generating the plurality of gray voltages N times more than the number of output gray voltages, further comprising analyzing an image histogram of the input data and, based thereon, generating the selection signal.

3. The method of claim 2, wherein, in analyzing the image histogram of the input data and generating the selection signal, the selection signal is generated using a predetermined color lookup table according to a result of analyzing the image histogram of the input data.

4. The method of claim 3, wherein, in analyzing the image histogram of the input data and generating the selection signal, the selection signal is generated for selecting output gray voltages of a region where a ratio of the output gray level to a gray level of the input data is less than 1, if the image histogram of the input data is in a low gray level region.

5. The method of claim 3, wherein, in analyzing the image histogram of the input data and generating the selection signal, the selection signal is generated for selecting output gray voltages of a region where a ratio of the output gray level to a gray level of the input data is greater than 1, if the image histogram of the input data is in a high gray level region.

6. A display driving apparatus that converts input data into a corresponding output voltage and displays an image, comprising:
a gray voltage generator generating a plurality of gray voltages N times more than a number of output gray voltages that represent voltage levels between a maximum value and a minimum value of the output voltage required to represent the input data as the image;
a gray voltage selector selecting a plurality of output gray voltages required to represent the image, from among the gray voltages N times more than the output gray voltages, in response to a selection signal; and
a decoding unit decoding the input data using the selected plurality of output gray voltages and generating the output voltage.

7. The apparatus of claim 6, further comprising a histogram analysis and image-processing unit analyzing an image histogram of the input data and, based thereon, generating the selection signal.

8. The apparatus of claim 7, wherein the histogram analysis and image-processing unit generates the selection signal using a predetermined color lookup table according to a result of analyzing the image histogram of the input data.

9. The apparatus of claim 8, wherein the histogram analysis and image-processing unit generates the selection signal for selecting output gray voltages of a region where a ratio of the output gray level to a gray level of the input data is less than 1, if the image histogram of the input data is in a low gray level region.

10. The apparatus of claim 8, wherein the histogram analysis and image-processing unit generates the selection signal for selecting output gray voltages of a region where a ratio of the output gray level to a gray level of the input data is greater than 1, if the image histogram of the input data is in a high gray level region.

11. The apparatus of claim 6, wherein the decoding unit comprises a plurality of decoders for decoding the input data and generating output voltages therefrom.

12. The apparatus of claim 6, further comprising a latch storing the input data and outputting the input data to the decoding unit.

13. A method of driving a display driving apparatus comprising:
analyzing an image histogram of M (M is a natural number) bits of input data and outputting M+K bits of corrected input data; and
latching the M+K bits of the corrected input data; and
decoding the M+K bits of the corrected input data using a plurality of gray voltages and generating an output voltage,
wherein the number of the plurality of gray voltages corresponds to the M+K bits of the corrected input data.

14. The method of claim 13, wherein K is a natural number.

15. The method of claim 13, wherein K is equal to a number of bits of input data lost due to image distortion.

16. A display driving apparatus comprising:
a histogram analysis and image-processing unit analyzing an image histogram of M (M is a natural number) bits of input data and outputting M+K bits of corrected input data;
a latch storing and outputting the M+K bits of the corrected input data;
a gray voltage generator outputting a gray level corresponding to the M+K bits of the corrected input data; and
a decoding unit decoding the M+K bits of the corrected input data output from the latch using the gray level and generating an output voltage.

17. The display driving apparatus of claim 16, wherein K is a natural number.

18. The display driving apparatus of claim 16, wherein K is equal to a number of bits of input data lost due to image distortion.
